(19) United States
(12) Patent Application Publication
(10) Pub. No.: US 2006/0056255 A1
(43) Pub. Date: Mar. 16, 2006

(54) Semiconductor memory apparatus and method for operating a semiconductor memory apparatus

(76) Inventor: Jean-Marc Dortu, Shibuya-ku (JP)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/215,640

(22) Filed: Aug. 30, 2005

(30) Foreign Application Priority Data
Aug. 30, 2004 (DE) 10 2004 041908.6

(51) Int. Cl. G11C 7/00

(52) U.S. Cl. 365/222

(57) ABSTRACT

The invention relates to a semiconductor memory apparatus and a method for operating a semiconductor memory apparatus which can be operated in a normal operating mode and in a self-refresh mode. The method comprises the following steps in the self-refresh mode: determining the operating temperature of the semiconductor memory apparatus; producing a temperature-dependent refresh signal, with a predetermined frequency value being associated with each operating temperature value; comparing the determined operating temperature with a first predetermined temperature value; and increasing the frequency of the refresh signal to a first predetermined frequency value when the determined operating temperature is less than or equal to the first predetermined temperature value.

### CROSS-REFERENCE TO RELATED APPLICATIONS

This application claims foreign priority benefits under 35 U.S.C. §119 to co-pending German patent application number DE 10 2004 041908.6, filed 30 Aug. 2004. This related patent application is herein incorporated by reference in its entirety.

### BACKGROUND OF THE INVENTION

1. Field of the Invention

The invention relates to a semiconductor memory apparatus and a method for operating a semiconductor memory apparatus.

2. Description of the Related Art

The memory cells in DRAM semiconductor memory apparatuses have to be periodically refreshed or updated in order to prevent loss of data. For this purpose, a signal is passed to the semiconductor memory apparatus and is used for the self-refresh. In particular, in this case, the content of the memory cells is first read, then amplified and then written to the memory cells again.

Methods are known in which the frequency of the refresh signal is dependent on the operating temperature of the semiconductor memory apparatus. In particular, in this case, the frequency of the refresh signal decreases as the temperature falls. One such method is known, for example, from U.S. Pat. No. 5,532,968.

Furthermore, it is known from U.S. 2004/00 22103 A1 for the frequency of the temperature-dependent refresh signal to be limited to a minimum value and a maximum value. In particular in this case, the self-refresh frequency is kept at a predetermined minimum value, for temperatures which are less than or equal to a predetermined minimum temperature.

The methods from the prior art have the disadvantage, however, that errors occur during the self-refresh process at very low operating temperatures.

Thus, there is a need to provide a method for operation of a semiconductor memory apparatus and a semiconductor memory apparatus which allow reliable and essentially error-free operation of the semiconductor memory apparatus, particularly at low temperatures.

### SUMMARY OF THE INVENTION

According to the invention, a method for operation of a semiconductor memory apparatus is provided, wherein the semiconductor memory apparatus can be operated in a normal operating mode and in a self-refresh mode, with the method comprising the following steps in the self-refresh mode:
determining the operating temperature or ambient temperature of the semiconductor memory apparatus;
producing a temperature-dependent and generally periodic refresh signal, with a predetermined frequency value being associated with each operating temperature value and with the frequency of the refresh signal decreasing in steps or continuously as the operating temperature decreases to a base temperature corresponding to a minimum refresh frequency;
comparing the determined operating temperature with a first predetermined temperature value which is lower than the base temperature;
increasing the frequency of the refresh signal to a first predetermined frequency value, when the determined operating temperature is less than or equal to the first predetermined temperature value.

Surprisingly, the number of errors produced during a self-refresh process can be reduced by increasing the self-refresh frequency, particularly at very low operating temperatures.

The first predetermined temperature value is, in particular, a very low temperature value. The first predetermined temperature value is preferably less than 0° C., furthermore preferably −10° C., and most preferably −20° C.

According to one preferred embodiment, for which the first predetermined temperature value is less than the second predetermined temperature value, the temperature-dependent frequency of the refresh signal is kept at a second predetermined frequency value when the determined operating temperature is less than or equal to a second predetermined temperature value but greater than the first predetermined temperature value.

Thus, for the frequency value of the temperature-dependent refresh signal to be kept at a second predetermined frequency value or minimum value, corresponding to a second predetermined temperature value, the refresh frequency is increased when the operating temperature falls below or is equal to a first predetermined temperature value. In this case, the first predetermined temperature value is lower than the second predetermined temperature value.

Preferably, the step of comparing the determined operating temperature with the first predetermined temperature value is carried out outside the semiconductor memory apparatus, in particular, in a controller which operates the semiconductor memory apparatus, and the step of fixing the frequency of the refresh signal at the first frequency value is carried out with the aid of a configuration command which is generated in particular by a controller which operates the semiconductor memory apparatus.

In particular in this case, a temperature sensor is provided outside the semiconductor memory apparatus, preferably in a controller which operates the semiconductor memory apparatus. When the temperature sensor finds that the first predetermined temperature value has been reached or undershot, the controller uses the next configuration command to pass an instruction to the semiconductor memory apparatus to increase the frequency of the refresh signal to the first predetermined frequency value.

The configuration command is preferably a mode register set command (also referred to as MRS command). The MRS command can be used, inter alia, to determine the burst length, the burst type, the CAS latency and an operating mode of the semiconductor memory apparatus. The MRS command is transmitted at least once at the start of operation of the circuit arrangement from the controller to the semiconductor memory apparatus. The MRS command can also be transmitted during operation of the semiconductor memory apparatus to the semiconductor memory apparatus, in order to transmit configuration instructions to the semiconductor memory apparatus.

Alternatively, the step of comparing the determined operating temperature with the first predetermined temperature value and the step of fixing the frequency of the refresh signal at the first frequency value are carried out internally in the semiconductor memory apparatus.

In particular, a temperature sensor, by means of which the operating temperature is determined, may be provided in the semiconductor memory apparatus. Furthermore, the semiconductor memory apparatus may be programmed in such a way that, when the operating temperature is found to be less than or equal to the first predetermined temperature value, the frequency of the self-refresh signal is increased to the first predetermined frequency value.

Preferably, a plurality of further temperature values are provided, which differ from one another and are in each case less than the first predetermined temperature value, and a plurality of further frequency values are provided, which differ from one another and are in each case greater than the first predetermined frequency value, a further frequency value is associated with each further temperature value and the associated frequency values each increase as the respectively associated temperature value falls. The method further comprises the following steps:
comparing the determined operating temperature with the further temperature values; and
when the determined operating temperature is less than or equal to a further temperature value, increasing the frequency of the refresh signal in each case to the further frequency value which is associated with the respective further temperature value.

The frequency of the self-refresh signal may be increased in steps as the temperature falls at very low temperatures. As an alternative, the increase in the self-refresh frequency may be carried out continuously (e.g., continuous ramp up) as the temperature falls at very low temperatures.

Furthermore, a semiconductor memory apparatus which can be operated in a normal operating mode and in a self-refresh mode is provided, the semiconductor memory apparatus comprising:
a device for determining the operating temperature of the semiconductor memory apparatus;
a device for producing a temperature-dependent refresh signal, with a predetermined frequency value being associated with each operating temperature value and the frequency of the refresh signal decreasing in steps or continuously as the operating temperature decreases to a base temperature corresponding to a minimum refresh frequency;
a device for comparing the determined operating temperature with a first predetermined temperature value which is lower than the base temperature; and
a device for increasing the frequency of the refresh signal to a first predetermined frequency value, when the determined operating temperature is less than or equal to the first predetermined temperature value.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a graph showing the relationship between the operating temperature and the self-refresh frequency; and

FIGS. 2A to 2C show profiles of the voltage in a memory cell during the self-refresh mode.

FIG. 3 is a block diagram illustrating a semiconductor memory device which can be operated in a normal operating mode and in a self-refresh mode according to one embodiment of the invention.

### DETAILED DESCRIPTION OF THE PREFERRED EMBODIMENT

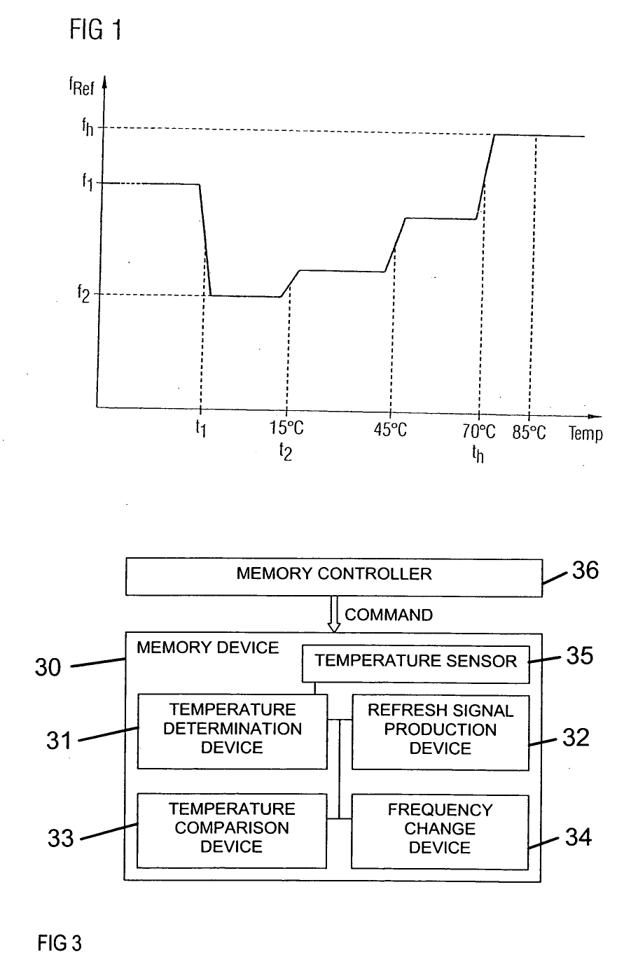

One preferred embodiment of the present invention will be described in the following text, with reference to FIG. 1.

The memory cells in a semiconductor memory apparatus each essentially comprise a capacitor and a transistor. The information contained in a memory cell is defined essentially by the state of charge of the capacitor. To be precise, when the semiconductor memory apparatus is actually in the operating state but no new information is written to the memory cells over a lengthy period of time, the information or voltage contained in the memory cells, in particular when the capacitors in the memory cells decays, owing to leakage currents. For this reason, the memory cells have to be periodically refreshed in this mode. During this process, the memory cell content is read, then amplified to a required level and then written back to the memory cell. Since the leakage currents increase with rising temperatures, it is necessary to carry out the self-refresh process more often at higher temperatures than at low temperatures. The self-refresh frequency may be increased in steps as the temperature rises. Alternatively, the self-refresh frequency may be increased continuously as the temperature rises.

FIG. 1 shows the profile of the self-refresh frequency F_{Ref} as a function of the operating temperature Temp of the semiconductor memory apparatus. In the illustrated profile, the refresh frequency is kept at a predetermined maximum frequency value fₕ for operating temperatures which are higher than a maximum predetermined operating temperature tₕ. As the temperature decreases, the losses resulting from leakage currents in the memory cells become less over time, so that the self-refresh frequency f_{Ref} can be reduced. In the illustrated embodiment, this is done in three steps. For temperatures which are lower than a temperature t₂, the self-refresh frequency f_{Ref} is kept at a minimum value f₂. This makes it possible to reduce the current drawn by the semiconductor memory apparatus during the self-refresh mode.

Provision is also made for the self-refresh frequency to be increased to a value f₁ which is higher than the minimum frequency value f₂, below a predetermined temperature t₁ which is lower than the temperature t₂.

The error rate during the self-refresh mode can surprisingly be reduced by increasing the self-refresh frequency at very low temperatures.

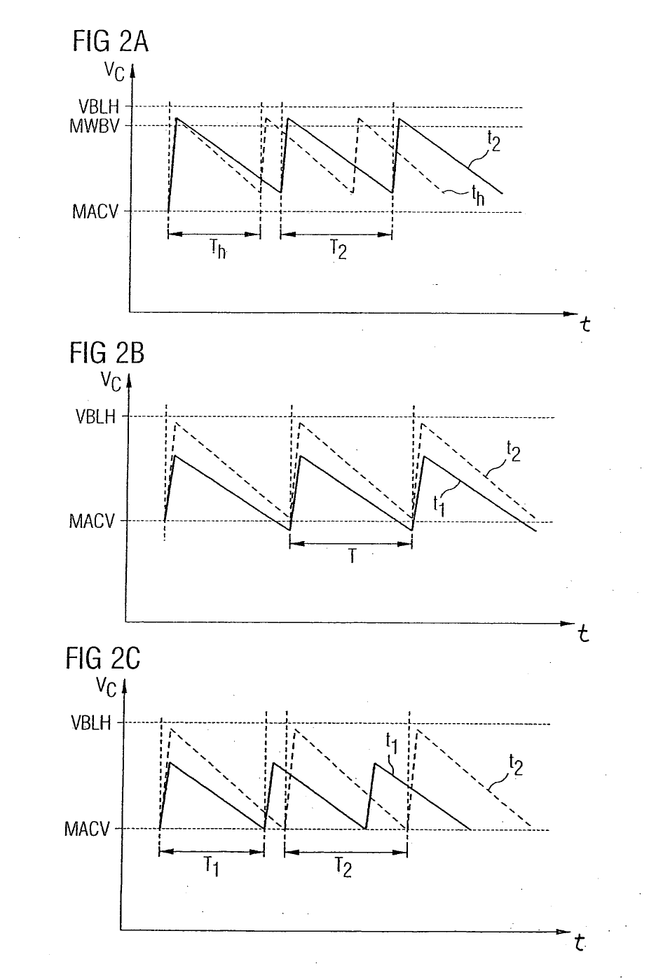

One possible explanation for this surprising and advantageous effect which is achieved by increasing the self-refresh frequency at very low temperatures will be explained in the following text with reference to FIGS. 2A to 2C.

FIGS. 2A to 2C show voltage profiles in one example of a memory cell in a semiconductor memory apparatus plotted against time during the refresh mode. In this case, the illustration in each case shows profiles for two different temperatures on a graph. Constant voltages VBLH, MWBV and MACV are also shown on the graphs. In this case, the value VBLH (voltage bit line high) represents the maximum voltage on the bit line of a memory cell in order to indicate a “high signal” on the bit line. The voltage MWBV (minimum write back voltage) is the minimum voltage which must be written to the memory cell during a refresh process in order to achieve a correct value in the memory cell, and MACV (minimum allowable cell voltage) is the minimum voltage which is permitted in a memory cell in order to make it possible to detect a logical “1”.

The profile of the memory cell voltage V_{c} will first be described for a high operating temperature tₕ and a medium operating temperature t₂, with reference to FIG. 2A. V_{c} is in this case essentially the voltage on the capacitor in the memory cell. The temperatures furthermore each correspond to the temperatures illustrated in FIG. 1. In the illustrated graph, tₕ corresponds to about 70° C. and t₂ to about 15° C. In this case t₂ is that minimum temperature below which the self-refresh frequency is kept at a constant minimum value f₂. These values have been chosen only by way of example for illustrative purposes, and other values could likewise have been chosen. The solid line on the graph in this case represents the profile for the temperature value t₂, and the dashed line on the graph represents the profile for the temperature value tₕ.

At high operating temperatures, the leakage currents in the storage memory cell are relatively high, and the voltage V_{c} in the memory cell therefore decays with a relatively steep gradient. After a self-refresh, the voltage rises again to the required value, and subsequently decays again. Owing to the steep gradient of the falling curve at high temperature, it is necessary to provide a high refresh signal frequency in order to ensure that the information contained in the memory cell is retained correctly. The period duration for the self-refresh signal annotated Tₕ is thus relatively short.

If, in contrast, the semiconductor memory apparatus is operated at a medium temperature t₂, the gradient of the falling curve is not as steep as during operation at the high temperature tₕ, and therefore the time in which the memory cell voltage V_{c} decays to a specific value is longer. The self-refresh frequency can thus be reduced in comparison with operation at high temperatures. The period duration of the self-refresh signal, which is annotated T₂, is in this case longer than the period duration Tₕ, for the higher temperature tₕ.

FIG. 2B shows a profile when the semiconductor memory apparatus is operated at two different temperatures, the minimum temperature t₂ and a temperature t₁ which is lower than this minimum temperature t₂. In this case, the self-refresh frequency f_{Ref} is kept at the same value for both temperatures. The period duration T of the self-refresh signal is thus the same for both temperatures. The profile of the voltage for the higher temperature value t₂ is similar to that shown in FIG. 2A. The leakage currents admittedly decrease again at lower temperatures but the resistances of the transistor of the memory cell increase at the same time. The voltage level while writing the amplified signal to the memory cell is thus lower than in the case of that of the operating temperature t₂. Since the maximum voltage which can be achieved during operation of the semiconductor memory apparatus at the low temperature t₁ is lower, the memory cell voltage falls below the minimum value MACV, which can lead to errors, in particular reading errors.

FIG. 2C shows a profile when the self-refresh frequency f_{Ref} is increased for very low temperatures which are less than or equal to the temperature t₁. The period duration T₁ is thus shorter than the period duration T₂. The maximum voltage to be reached can admittedly not be increased, although it is in this case possible to prevent the voltage profile in the memory cell from falling below the minimum value MACV. The rate at which errors occur can thus be reduced.

In addition to the embodiment illustrated in FIG. 1, the self-refresh frequency may be increased when the operating temperature is below the low temperature t₁ in order to compensate for the increase in the resistances of the transistor in the memory cell at low temperatures. This increase may be either continuous or in stepped form.

FIG. 3 is a block diagram illustrating a semiconductor memory device which can be operated in a normal operating mode and in a self-refresh mode according to one embodiment of the invention. The semiconductor memory device 30 comprises:
a temperature determination device 31 for determining the operating temperature of the semiconductor memory apparatus;
a refresh signal production device 32 for producing a temperature-dependent refresh signal, with a predetermined frequency value being associated with each operating temperature value and the frequency of the refresh signal decreasing in steps or continuously as the operating temperature decreases to a base temperature corresponding to a minimum refresh frequency;
a temperature comparison device 33 for comparing the determined operating temperature with a first predetermined temperature value which is lower than the base temperature; and
a frequency change device 34 for increasing the frequency of the refresh signal to a first predetermined frequency value when the determined operating temperature is less than or equal to the first predetermined temperature value.

The operating temperature of the semiconductor memory apparatus may be determined in the semiconductor memory apparatus itself, preferably with the aid of a temperature sensor 35 integrated therein. In this case, the semiconductor memory apparatus is preferably programmed such that the frequency of the self-refresh signal is increased to the first frequency value f₁ (which can be predetermined), when the operating temperature falls below the first temperature value t₁ (which can be predetermined).

As an alternative to this, the operating temperature of the semiconductor memory apparatus may be determined in a controller 36 which operates the semiconductor memory apparatus. In this case, by way of example, a configuration command can be used to transmit an instruction to the semiconductor memory apparatus to increase the self-refresh frequency to the first predetermined frequency value f₁, when the operating temperature is less than or equal to the first predetermined temperature t₁.

The configuration command is preferably a mode register set command (or MRS command) or an extended mode register set command (or EMRS command). The MRS command can be used, inter alia, to define the burst length, the burst type, the CAS latency and an operating mode of the semiconductor memory apparatus. The MRS command is transmitted by the controller to the semiconductor memory apparatus at least once at the start of operation of the circuit arrangement. Furthermore, the MRS command can also be transmitted to the semiconductor memory apparatus during operation of the semiconductor memory apparatus in order to transmit configuration instructions to the semiconductor memory apparatus.

The first predetermined temperature value t₁ is preferably a very low temperature value. The first predetermined temperature value is preferably less than 0° C., furthermore preferably −10° C., and most preferably −20° C.

While the foregoing is directed to embodiments of the present invention, other and further embodiments of the invention may be devised without departing from the basic scope thereof, and the scope thereof is determined by the claims that follow.

What is claimed is:

1. A method for operating a semiconductor memory apparatus having a normal operating mode and a self-refresh mode, the method comprising, in the self-refresh mode:
producing a temperature-dependent periodic refresh signal having a defined frequency-temperature relationship in which a frequency value of the signal increases as the operating temperature increases from a base temperature value corresponding to a minimum refresh frequency value;
determining an operating temperature of the semiconductor memory apparatus; and
increasing the frequency value of the refresh signal to a first predetermined frequency value when the determined operating temperature is less than the base temperature value.

2. The method of claim 1, wherein increasing the frequency value of the refresh signal to the first predetermined frequency value is done when the determined operating temperature is less than a first predetermined temperature value which is lower than the base temperature value.

3. The method of claim 2, wherein the frequency value of the refresh signal is set at a base frequency value when the determined operating temperature is greater than the first predetermined temperature value but less than or equal to the base temperature value.

4. The method of claim 1, further comprising comparing the determined operating temperature with a first predetermined temperature value which is lower than the base temperature value; and wherein increasing the frequency value of the refresh signal to the first predetermined frequency value is done when the determined operating temperature is less than the first predetermined temperature value.

5. The method of claim 4, wherein the step of comparing the determined operating temperature with the first temperature value is carried out outside the semiconductor memory apparatus by a memory controller, and wherein the step of increasing the frequency value of the refresh signal to the first frequency value is carried out utilizing a configuration command sent by the memory controller.

6. The method of claim 4, wherein the step of comparing the determined operating temperature with the first temperature value and the step of increasing the frequency value of the refresh signal to the first frequency value are performed by one or more devices disposed within the semiconductor memory apparatus.

7. The method of claim 1, further comprising:
providing a plurality of further temperature values and associated frequency values, wherein each further temperature value is decreasing lower than the first temperature value and each associated frequency value is increasingly higher than the first frequency value, respectively;
comparing the determined operating temperature with the further temperature values; and
when the determined operating temperature is less than or equal to a respective further temperature value, increasing the frequency value of the refresh signal to a respective associated further frequency value.

8. The method of claim 1, wherein the frequency value of the refresh signal is increased in stepped levels, each level corresponding to a temperature range.

9. The method of claim 1, wherein the frequency value of the refresh signal is increased as a continuous ramp function.

10. The method of claim 1, wherein the first predetermined temperature value is equal to or less than 0° C.

11. A semiconductor memory apparatus having a normal operating mode and a self-refresh mode, the semiconductor memory apparatus comprising:
a temperature determination device for determining an operating temperature of the semiconductor memory apparatus;
a refresh signal production device for producing a temperature-dependent periodic refresh signal having a frequency value which increases as the operating temperature increases from a base temperature value corresponding to a minimum refresh frequency value; and
a frequency changing device for increasing the frequency value of the refresh signal to a first predetermined frequency value when the determined operating temperature is less than the base temperature value.

12. The memory apparatus of claim 11, further comprising:
a temperature comparison device for comparing the determined operating temperature with a first predetermined temperature value which is lower than the base temperature value, wherein the frequency changing device increases the frequency value of the refresh signal to the first predetermined frequency value when the determined operating temperature is less than or equal to the first predetermined temperature value.

13. The memory apparatus of claim 12, wherein the frequency value of the refresh signal is set at a base frequency value when the determined operating temperature is greater than the first predetermined temperature value but less than or equal to the base temperature value.

14. The memory apparatus of claim 12, further comprising:
a memory controller for comparing the determined operating temperature with the first temperature value and for sending a configuration command to increase the frequency value of the refresh signal to the first frequency value.

15. The memory apparatus of claim 14, wherein the temperature determination device is disposed as a component of the memory controller and comprises a temperature sensor for determining the operating temperature.

16. The memory apparatus of claim 12,
wherein a plurality of further temperature values and associated frequency values are provided, wherein each further temperature value is decreasing lower than the first temperature value and each associated frequency value is increasingly higher than the first frequency value, respectively;
wherein the temperature comparison device is further configured to compare the determined operating temperature with the further temperature values; and
wherein, when the determined operating temperature is less than or equal to a respective further temperature value, the frequency changing device is further configured to increase the frequency value of the refresh signal to a respective associated further frequency value.

17. A method for operating a memory device in a self-refresh mode, the method comprising:
determining an operating temperature of the memory device; and
producing a temperature-dependent periodic refresh signal having a refresh signal frequency value based on the determined operating temperature, wherein a minimum refresh frequency value is set for a temperature range between a first temperature value and a second temperature value which is higher than the first temperature value, wherein the refresh signal frequency value increases as an operating temperature of the memory device falls below the first temperature value and wherein the refresh signal frequency value increases as the operating temperature of the memory device rises above the second temperature value.

18. The method of claim 17, wherein the refresh signal frequency value is increased as a continuous ramp function.

19. The method of claim 17, wherein a plurality of refresh signal frequency values are provided, each corresponding to a respective temperature range.

20. The method of claim 17, wherein a first plurality of refresh signal frequency values are provided, each corresponding to a respective temperature range below the first temperature value, and a second plurality of refresh signal frequency values are provided, each corresponding to a respective temperature range above the second temperature value.

21. The method of claim 17, wherein the operating temperature is determined utilizing a memory controller disposed apart from memory device, and wherein the refresh signal frequency value is set based on a configuration command sent by the memory controller.

22. The method of claim 17, wherein the operating temperature is determined utilizing a temperature sensor and a temperature determination device disposed as components of the memory device, and wherein the refresh signal frequency value is produced by a refresh signal production device disposed as a component of the memory device.
